(19) United States
(12) Patent Application Publication
(10) Pub. No.: US 2025/0304733 A1
(43) Pub. Date: Oct. 2, 2025

(54) CURABLE COMPOSITION, CURED LAYER USING THE COMPOSITION, COLOR FILTER INCLUDING THE CURED LAYER AND DISPLAY DEVICE INCLUDING THE COLOR FILTER

(71) Applicant: SAMSUNG SDI CO., LTD., Yongin-si (KR)

(72) Inventors: Mingi KIM, Suwon-si (KR); Kyuyoung KIM, Suwon-si (KR); Insub SHIN, Suwon-si (KR); Minsung KIM, Suwon-si (KR); Jonggi KIM, Suwon-si (KR); Chunkeun JANG, Suwon-si (KR)

(73) Assignee: SAMSUNG SDI CO., LTD., Yongin-si (KR)

(21) Appl. No.: 19/073,580

(22) Filed: Mar. 7, 2025

(30) Foreign Application Priority Data
Mar. 29, 2024 (KR) 10-2024-0043582

(51) Int. Cl. C08F 220/38; C08F 220/06; C08K 3/22; C08K 5/053; G02B 5/22

(52) U.S. Cl. CPC C08F 220/382; C08F 220/06; C08K 3/22; C08K 5/053; C08K 2003/2241; G02B 5/223

(57) ABSTRACT

Examples of the disclosure include a curable composition, a cured layer manufactured including the curable composition, a color filter including the cured layer, and a display device including the cured layer. The curable composition includes quantum dots and a polymerizable compound, wherein the polymerizable compound includes a first polymerizable compound having high refractive and high viscosity characteristics.

### CROSS-REFERENCE TO RELATED APPLICATION

This application claims the benefit of priority to Korean Patent Application No. 10-2024-0043582 filed in the Korean Intellectual Property Office on Mar. 29, 2024, the entire contents of which are incorporated herein by reference.

### BACKGROUND OF THE DISCLOSURE

### (a) Field of the Disclosure

Examples of this disclosure relate to a curable composition, a cured layer using the composition, a color filter including the cured layer, and a display device including the color filter.

### (b) Description of the Related Art

In the case of general quantum dots, due to surface characteristics having hydrophobicity, a solvent in which a quantum dot is dispersed is limited, and thus, it may be challenging to introduce the quantum dot into a polar system such as, e.g., a binder, or a curable monomer.

For example, even in the case of a quantum dot ink composition being actively researched, a polarity of the quantum dot ink composition is relatively low in an initial operation, and the quantum dot ink composition may be dispersed in a solvent in a curable composition having a high hydrophobicity. Therefore, because 20 wt % or more of quantum dots may be challenging to be included based on a total amount of the composition, it is challenging to increase light efficiency of the ink over a given level. Even though the quantum dots are additionally added and dispersed in order to increase light efficiency, the viscosity of the ink exceeds a range capable of ink-jetting and thus processability may not be satisfied.

In order to achieve the viscosity range capable of ink-jetting, example embodiments include a method of lowering an ink solid content by dissolving 50 wt % or more of a solvent based on a total amount of the composition, which also provides a somewhat satisfactory result in terms of viscosity. However, it may be considered to be a satisfactory result in terms of a viscosity, but nozzle drying due to solvent volatilization, nozzle clogging, and thickness reduction of single film as time passes after jetting may become worse, and it may be challenging to control a thickness deviation after curing. Thus, it may be challenging to apply the ink to actual processes.

Therefore, a solvent-free quantum dot ink that does not include a solvent is a desirable form to be applied to an actual process. The current technique of applying a quantum dot to a solvent type composition is now limited to a given extent.

A solvent-free curable composition (quantum dot ink compositions), includes an excessive amount of polymerizable compound, and brings about challenges of nozzle clogging and discharge failures according to nozzle drying due to volatility, and thickness reduction of a single film due to volatilization of the ink composition jetted in a pattern partition wall pixel. Therefore, efforts are being made to improve the optical characteristics of solvent-free curable composition. In order to improve the optical characteristics of a solvent-free curable composition, a method of increasing the content of inorganic materials is generally used, but presents challenges in that, as the content of inorganic materials increases, the reflectance increases. In other words, improving optical characteristics and reducing reflectance of solvent-free curable compositions are in a trade-off relationship, and there is a need for technology that can improve both properties simultaneously or contemporaneously, e.g., improving optical characteristics and reducing reflectance.

### SUMMARY OF THE DISCLOSURE

Some example embodiments include a curable composition that can simultaneously or contemporaneously improve optical characteristics and reduce reflectance.

Some example embodiments include a cured layer produced using the curable composition.

Some example embodiments include a color filter including the cured layer.

Some example embodiments include a display device including the color filter.

Some example embodiments include a curable composition including (A) quantum dots, and (B) a polymerizable compound, wherein the polymerizable compound includes a first polymerizable compound represented by Chemical Formula 1.

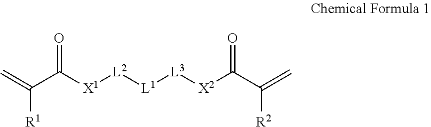

In Chemical Formula 1,
R¹ and R² each independently are or include a hydrogen atom or a substituted or unsubstituted C1 to C20 alkyl group,
L¹ to L³ each independently are or include at least one of a single bond, an ether group (*—O—*), or a substituted or unsubstituted C1 to C20 alkylene group, and
X¹ and X² each independently are or include at least one of an ether group (*—O—*) or a sulfide group (*—S—*), provided that at least one of X¹ and X² is a sulfide group (*—S—*).

L¹ may be or include at least one of a single bond, an ether group (*—O—*), or a substituted or unsubstituted C1 to C20 alkylene group.

L² and L³ may each independently be or include a substituted or unsubstituted C1 to C20 alkylene group.

The first polymerizable compound may have a refractive index that is greater than or equal to about 1.49, and a viscosity that is greater than or equal to about 7.0.

The first polymerizable compound may be represented by any one of Chemical Formula 1-1 to Chemical Formula 1-3.

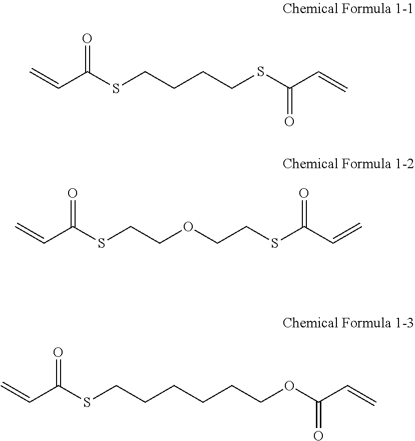

The polymerizable compound may further include a second polymerizable compound having a different structure from the first polymerizable compound.

The second polymerizable compound may include a compound represented by Chemical Formula 2.

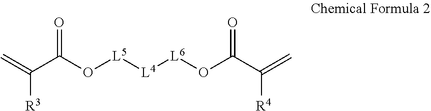

In Chemical Formula 2,
L⁴ is or includes at least one of a substituted or unsubstituted C1 to C10 alkylene group, a substituted or unsubstituted C3 to C20 cycloalkylene group, or an ether group (*—O—*),
L⁵ and L⁶ each independently are or include at least one of a single bond or a substituted or unsubstituted C1 to C10 alkylene group, and
R³ and R⁴ each independently are or include at least one of a hydrogen atom or a substituted or unsubstituted C1 to C20 alkyl group.

The first polymerizable compound and the second polymerizable compound may be included in a weight ratio in a range of about 1:9 to about 9:1.

The first polymerizable compound and the second polymerizable compound may be included in a weight ratio in a range of about 1:9 to about 5:5.

The curable composition may be or include a solvent-free curable composition.

Based on a total amount of the solvent-free curable composition, the solvent-free curable composition may include about 5 wt % to about 60 wt % of the quantum dots, and about 40 wt % to about 95 wt % of the polymerizable compound.

The curable composition may further include at least one of a polymerization initiator, a light diffusing agent, a polymerization inhibitor, or a combination thereof.

The light diffusing agent may include at least one of barium sulfate, calcium carbonate, titanium dioxide, zirconia, or a combination thereof.

The curable composition may further include a solvent.

The curable composition may include about 1 wt % to about 40 wt % of the quantum dots, about 1 wt % to about 20 wt % of the polymerizable compound, and about 40 wt % to about 80 wt % of the solvent based on a total weight of the curable composition.

The curable composition may further include at least one of malonic acid; 3-amino-1,2-propanediol; a silane-based coupling agent; a leveling agent; a fluorine-based surfactant; or a combination thereof.

Some example embodiments include a cured layer manufactured using the curable composition.

Some example embodiments include a color filter including the cured layer.

Some example embodiments include a display device including the color filter.

Other example embodiments of the present disclosure are included in the following detailed description.

By including a polymerizable compound having high refractive and high viscosity properties in the curable composition containing quantum dots, the optical characteristics of the curable composition containing quantum dots may be improved while simultaneously or contemporaneously reducing reflectance.

### DETAILED DESCRIPTION

Hereinafter, example embodiments of the present disclosure are described in detail. However, these embodiments are examples, the present disclosure is not limited thereto and the present disclosure is defined by the scope of claims.

As used herein, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As used herein, when specific definition is not otherwise provided, “substituted” refers to replacement of at least one hydrogen atom by a substituent including at least one of a halogen atom (F, Cl, Br, or I), a hydroxy group, a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, when specific definition is not otherwise provided, “hetero” refers to inclusion of at least one heteroatom of N, O, S, and P, in the chemical formula.

As used herein, when specific definition is not otherwise provided, “(meth)acrylate” refers to both “acrylate” and “methacrylate,” and “(meth)acrylic acid” refers to “acrylic acid” and “methacrylic acid.”

As used herein, when specific definition is not otherwise provided, the term “combination” refers to mixing or copolymerization.

In the present specification, when a definition is not otherwise provided, hydrogen is bonded at the position when a chemical bond is not drawn in chemical formula where supposed to be given.

In addition, in the present specification, when a definition is not otherwise provided, “*” refers to a linking point with the same or different atom or chemical formula.

In addition, unless otherwise specified herein, viscosity indicates viscosity at about 20° C.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

Hereinafter, each component constituting the curable composition according to some example embodiments will be described in detail.

### Polymerizable Compound

In the case of panels using quantum dots, there is a technical challenge of improving the luminance of the pixels and reducing external light reflection to improve the front-side luminance. To solve this problem, attempts have been made to increase the absorption rate (abs.) and light efficiency (EQE) of curable compositions including quantum dots. In general, the optical characteristics of a curable composition including quantum dots are improved as an amount of inorganic materials in the composition increases. For example, light efficiency can be improved by increasing an amount of quantum dot particles, or increasing the content of the light diffusing agent, which is a scattering agent. However, in this case, the reflectance may increase.

In addition to the amount of inorganic materials, light efficiency can be improved by using a monomer with a high refractive index, optical characteristics can be improved by using a high-viscosity monomer, and the structure of a new high refractive index/high viscosity polymerizable compound applicable to quantum dot-containing curable compositions (including both solvent-free and solvent-type) constitutes examples of the disclosure. That is, according to some example embodiments, light efficiency can be substantially improved by applying a new high refractive index/high viscosity curable monomer capable of improving optical characteristics and reducing reflectance of a curable composition including quantum dots.

The quantum dot-containing curable composition according to some example embodiments includes a (meth)acrylate compound having high refractive and high viscosity characteristics as a polymerizable compound, thereby simultaneously or contemporaneously improving optical characteristics and reducing reflectance of the curable composition. In particular, because the (meth)acrylate compound having high refractive/high viscosity characteristics in the quantum dot-containing curable composition according to some example embodiments is a thioacrylate-based monomer, the effect of improving optical characteristics can be improved or maximized.

For example, the (meth)acrylate compound having high refractive and high viscosity characteristics may be represented by Chemical Formula 1, and may be represented as the first polymerizable compound.

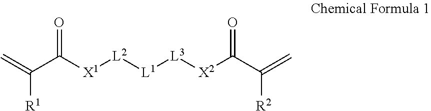

In Chemical Formula 1,
R¹ and R² each independently are or include at least one of a hydrogen atom or a substituted or unsubstituted C1 to C20 alkyl group,
L¹ to L³ each independently are or include at least one of a single bond, an ether group (*—O—*) or a substituted or unsubstituted C1 to C20 alkylene group, and
X¹ and X² each independently are or include at least one of an ether group (*—O—*) or a sulfide group (*—S—*), and at least one of X¹ and X² is necessarily a sulfide group (*—S—*).

The first polymerizable compound represented by Chemical Formula 1 may be a thioacrylate-based monomer. In this case, high refractive and high viscosity characteristics can be obtained simultaneously or contemporaneously, and the first polymerizable compound can be applied as a high refractive monomer to all types of quantum dot-containing curable composition, regardless of the presence or absence of a solvent, whether solvent-free or solvent-type. The optical characteristics of the cured layer manufactured using the quantum dot-containing curable composition applied in this way can be improved or maximized.

In addition, the linking groups L¹ to L³ in the first polymerizable compound represented by Chemical Formula 1 may not include a sulfide group, and it may be desirable that the sulfide group is directly bonded to the carbon constituting the carbonyl group. When L¹ to L³ includes a sulfide group, both the refractive index and viscosity may be lowered, which may be undesirable.

For example, in Chemical Formula 1, L¹ may be or include at least one of a single bond, an ether group (*—O—*), or a substituted or unsubstituted C1 to C20 alkylene group, and L² and L³ may each independently be a substituted or unsubstituted C1 to C20 alkylene group. In this case, the dispersibility of the quantum dots described later in the polymerizable compound can be further improved.

For example, the first polymerizable compound may have a refractive index that is greater than or equal to about 1.49, for example, greater than or equal to about 1.49, and less than or equal to about 1.7.

For example, the first polymerizable compound may have a viscosity that is greater than or equal to about 7.0, for example, greater than or equal to about 7.0 and less than or equal to about 15.

Because the first polymerizable compound represented by Chemical Formula 1 has a high refractive index and viscosity in the above ranges, the optical characteristics of the quantum dot-containing curable composition including the first polymerizable compound as a polymerizable compound can be substantially improved while the reflectance can be reduced.

On the other hand, the green quantum dot-containing curable composition has a disadvantage in that the absorption rate (abs.) and light efficiency (EQE) are relatively low compared to the red quantum dot-containing curable composition, and the reflectance is nearly twice as high. Therefore, there remains a technical challenge of improving the luminance of the green quantum dot pixels in the panel and further improving the front-side luminance by reducing external light reflection.

Example embodiments of the disclosure address the above challenges by applying the compound represented by Chemical Formula 1 as a polymerizable compound.

In general, the main method used to improve the optical characteristics of green quantum dot-containing curable composition is to increase an amount of inorganic materials, and conversely, the main method used to reduce the reflectance of the green quantum dot-containing curable composition is to increase an amount content of inorganic materials. Since the improvement of optical characteristics and reduction of reflectance are opposite physical properties, that is, improvement of optical characteristics and reduction of reflectance are in a trade-off relationship, it may be challenging to achieve the two properties at the same time.

According to some example embodiments, by applying the first polymerizable compound represented by Chemical Formula 1 to the curable composition, effects of improving optical properties and reducing reflectance can be simultaneously or contemporaneously achieved not only in a red quantum dot-containing curable composition but also in a green quantum dot-containing curable composition.

For example, the compound represented by Chemical Formula 1 may be represented by any one of Chemical Formulas 1-1 to 1-3, but is not necessarily limited thereto.

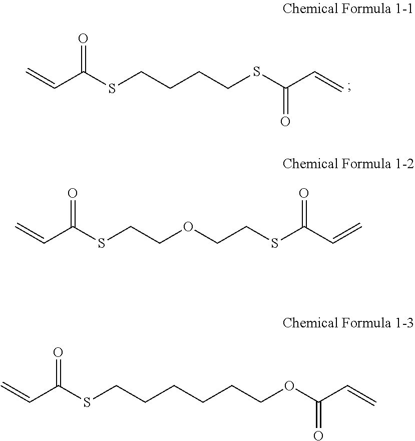

For example, the polymerizable compound may further include a compound (second polymerizable compound) having a different structure from the compound represented by Chemical Formula 1. That is, the polymerizable compound may include a compound represented by Chemical Formula 1 (first polymerizable compound) and another compound (second polymerizable compound) having a different structure.

For example, the second polymerizable compound having a different structure from the compound represented by Chemical Formula 1 may include a compound represented by Chemical Formula 2.

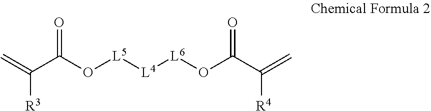

In Chemical Formula 2,
L⁴ is or includes at least one of a substituted or unsubstituted C1 to C10 alkylene group, a substituted or unsubstituted C3 to C20 cycloalkylene group, or an ether group (*—O—*),
L⁵ and L′ each independently are or include at least one of a single bond or a substituted or unsubstituted C1 to C10 alkylene group, and
R³ and R⁴ each independently are or include at least one of a hydrogen atom or a substituted or unsubstituted C1 to C20 alkyl group.

When the curable composition according to some example embodiments may further include a high refractive/high viscosity compound represented by Chemical Formula 1, and additionally a compound represented by Chemical Formula 2 as polymerizable compounds. the effects of improving optical characteristics, reducing reflectance, and improving inkjetting properties of the curable composition can be also achieved simultaneously or contemporaneously, as in the case of using the compound represented by Chemical Formula 1 alone.

For example, the compound represented by Chemical Formula 2 may have a refractive index that is less than or equal to about 1.455. When the compound represented by Chemical Formula 2 has a refractive index exceeding about 1.455, the compound represented by Chemical Formula 2 is advantageous for improving optical characteristics, but may be disadvantageous in terms of reducing reflectance.

For example, the compound represented by Chemical Formula 1 and the compound having a different structure from the compound represented by Chemical Formula 1 (e.g., the compound represented by Chemical Formula 2) may be included in a weight ratio in a range of about 1:9 to about 9:1, for example, a range of about 1:9 to about 5:5.

For example, the compound represented by Chemical Formula 1 may be included in an amount that is equal to or less than a compound having a structure different from the compound represented by Chemical Formula 1 (for example, the compound represented by Chemical Formula 2).

When the compound represented by Chemical Formula 1 is included in the same as or less amount than a compound having a different structure from the compound represented by Chemical Formula 1 (e.g., a compound represented by Chemical Formula 2), for example the compound represented by Chemical Formula 1 and the compound having a different structure from the compound represented by Chemical Formula 1 (e.g., a compound represented by Chemical Formula 2) are included in a weight ratio in a range of about 1:9 to about 5:5, the curing rate of the curable composition according to some example embodiments increases, it is possible to improve or maximize the simultaneous or contemporaneous goal of improving optical characteristics and reducing reflectance.

For example, the compound represented by Chemical Formula 2 may be represented by Chemical Formulas 2-1, 2-2, or 2-3, but is not necessarily limited thereto.

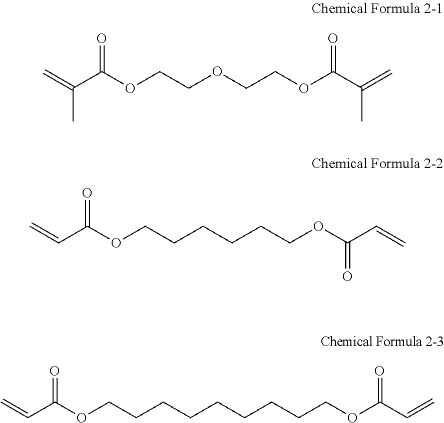

For example, the compound having a different structure from the compound represented by Chemical Formula 1 may further include, in addition to the compounds represented by Chemical Formula 2-1 to Chemical Formula 2-3, at least one of ethylene glycoldiacrylate, triethylene glycoldiacrylate, 1,4-butanedioldiacrylate, 1,6 hexanedioldiacrylate, neopentylglycoldiacrylate, pentaerythritoldiacrylate, pentaerythritoltriacrylate, dipentaerythritoldiacrylate, dipentaerythritoltriacrylate, dipentaerythritolpentaacrylate, pentaerythritolhexaacrylate, bisphenol A diacrylate, trimethylolpropanetriacrylate, novolacepoxyacrylate, ethylene glycoldimethacrylate, triethylene glycoldimethacrylate, propylene glycoldimethacrylate, 1,4-butanedioldimethacrylate, 1,6-hexanedioldimethacrylate, or a combination thereof.

For example, in addition to the polymerizable compound, monomers commonly used in conventional thermosetting or photocuring compositions may be further used. For example, the monomer may further include an oxetane-based compound such as bis [1-ethyl(3-oxetanyl)]methyl ether.

For example, the curable composition may be or include a solvent-free curable composition. In this case, based on the total amount of the solvent-free curable composition, the polymerizable compound may be included in an amount in a range of about 40 wt % to about 95 wt %, for example, about 50 wt % to about 90 wt %. When an amount of the polymerizable compound is within any of the above ranges, it is possible to manufacture a solvent-free curable composition having a viscosity capable of ink jetting. Additionally, the quantum dots in the prepared solvent-free curable composition can have desired or improved dispersibility, thereby improving optical characteristics.

For example, the polymerizable compound may have a molecular weight in a range of about 170 g/mol to about 1,000 g/mol. When the molecular weight of the polymerizable compound is within the above range, the polymerizable compound may be advantageous for ink-jetting because the polymerizable compound does not impair the optical characteristics of quantum dots and does not increase the viscosity of the composition.

In addition, when the curable composition includes a solvent, based on a total amount of the curable composition, the polymerizable compound may be included in an amount in a range of about 1 wt % to about 20 wt %, about 1 wt % to about 15 wt %, for example, about 5 wt % to about 15 wt %. When the polymerizable compound is included within any of the above ranges, optical characteristics of the quantum dots may be improved.

### Quantum Dot

For example, the quantum dots may have a maximum fluorescence emission wavelength in a range of about 500 nm to about 680 nm.

For example, when the curable composition according to some example embodiments is a solvent-free curable composition, an amount of the quantum dots may be in a range of about 5 wt % to about 60 wt %, for example about 10 wt % to about 60 wt %, for example about 20 wt % to about 60 wt %, for example about 30 wt % to about 50 wt %. When the quantum dots are included within any of the above ranges, high light retention and light efficiency can be achieved even after curing.

For example, when the curable composition according to some example embodiments includes a solvent, the quantum dots may be included in an amount in a range of about 1 wt % to about 40 wt %, for example about 3 wt % to about 30 wt %, based on a total amount of the curable composition. When the quantum dots are included within any of the above ranges, the light conversion rate is improved and pattern characteristics and development characteristics are not impaired, so that desired or improved processability may be obtained.

For example, the quantum dots absorb light in a wavelength region of about 360 nm to about 780 nm, for example about 400 nm to about 780 nm, and emits fluorescence in a wavelength region of about 500 nm to about 700 nm, for example about 500 nm to about 580 nm, or emits fluorescence in a wavelength region of about 600 nm to about 680 nm. That is, the quantum dots may have a maximum fluorescence emission wavelength (fluorescence λₑₘ) at about 500 nm to about 680 nm.

The quantum dots may each independently have a full width at half maximum (FWHM) in a range of about 20 nm to about 100 nm, for example a range of about 20 nm to about 50 nm. When the quantum dots have a full width at half maximum (FWHM) in any of the above ranges, color gamut is increased when used as a color material in a color filter due to high color purity.

The quantum dots may each independently be or include at least one of an organic material, an inorganic material, or a hybrid (mixture) of an organic material and an inorganic material.

The quantum dots may each independently be composed of or include a core and a shell surrounding the core, and the core and the shell may each independently have a structure of a core, core/shell, core/first shell/second shell, alloy, alloy/shell, or the like, which is composed of Group II-IV, Group III-V, and the like, but are not limited thereto.

For example, the core may include at least at least one material such as at least one of CdS, CdSe, CdTe, ZnS, ZnSe, ZnTe, HgS, HgSe, HgTe, GaN, GaP, GaAs, InP, InAs, and an alloy thereof, but is not necessarily limited thereto. The shell surrounding the core may include at least one material such as at least one of CdSe, ZnSe, ZnS, ZnTe, CdTe, PbS, TiO, SrSe, HgSe, and an alloy thereof, but is not necessarily limited thereto.

In some example embodiments, because concern for environment is increasing, and restrictions on toxic materials are strengthened, a cadmium-free light emitting material (InP/ZnS, InP/ZnSe/ZnS, etc.) having little low quantum efficiency (quantum yield) but being environmentally-friendly instead of a light emitting material having a cadmium-based core may be advantageous, but not necessarily limited thereto.

In the case of the quantum dots of the core/shell structure, an entire size including the shell (an average particle diameter) may be in a range of about 1 nm to about 15 nm, for example, a range of about 5 nm to about 15 nm.

For example, the quantum dots may each independently include red quantum dots, green quantum dots, or a combination thereof. The red quantum dots may each independently have an average particle diameter in a range of about 10 nm to about 15 nm. The green quantum dots may each independently have an average particle diameter in a range of about 5 nm to about 8 nm.

On the other hand, for dispersion stability of the quantum dot, the curable composition according to some example embodiments may further include a dispersant. The dispersant helps uniform dispersibility of light conversion materials such as quantum dots in the curable composition, and may include at least one of a non-ionic, anionic, or cationic dispersant. For example, the dispersant may be or include at least one of polyalkylene glycol or esters thereof, a polyoxy alkylene, a polyhydric alcohol ester alkylene oxide addition product, an alcohol alkylene oxide addition product, a sulfonate ester, a sulfonate salt, a carboxylate ester, a carboxylate salt, alkyl amide alkylene oxide addition product, alkyl amine and the like, and the components of the dispersant may be included alone or in a mixture of two or more components. The dispersant may be present in an amount in a range of about 0.1 wt % to about 100 wt %, for example about 10 wt % to about 20 wt % based on a solid content of the light conversion material such as quantum dots.

For example, the quantum dots may be surface-modified with a ligand having a polar group, for example, a ligand having high affinity for the polymerizable compound. In the case of surface-modified quantum dots as described above, high-concentration or highly concentrated quantum dot dispersions (improvement of the dispersibility of quantum dots in polymerizable compounds) may be readily manufactured, which can have a significant impact on improving light efficiency, especially in the implementation of solvent-free curable compositions.

For example, the ligand having a polar group may have a structure with high affinity to the chemical structure of the polymerizable compound.

For example, the ligand having the polar group may be represented by any one of the compounds represented by Chemical Formula A to Chemical Formula Q below, but is not necessarily limited thereto.

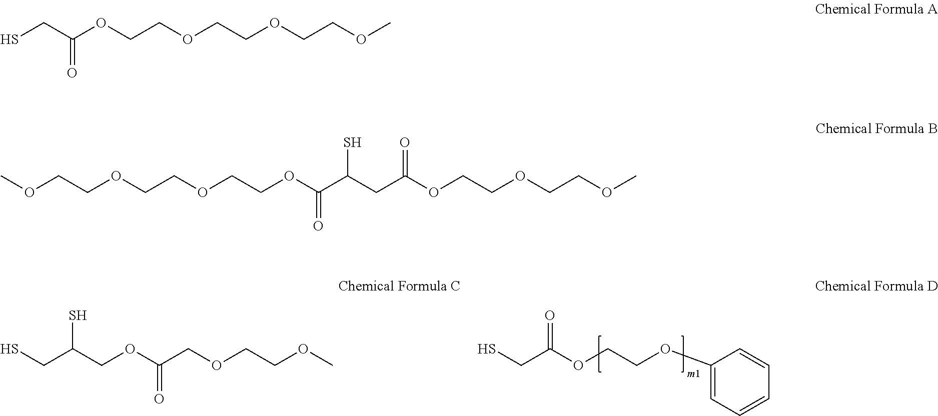

In Chemical Formula D, ml is an integer in a range of 0 to 10.

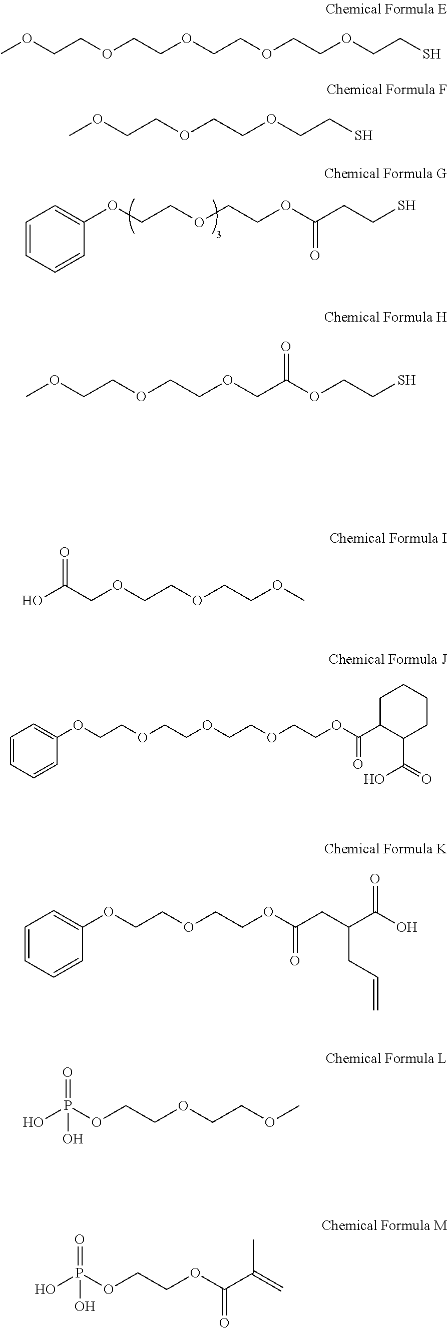

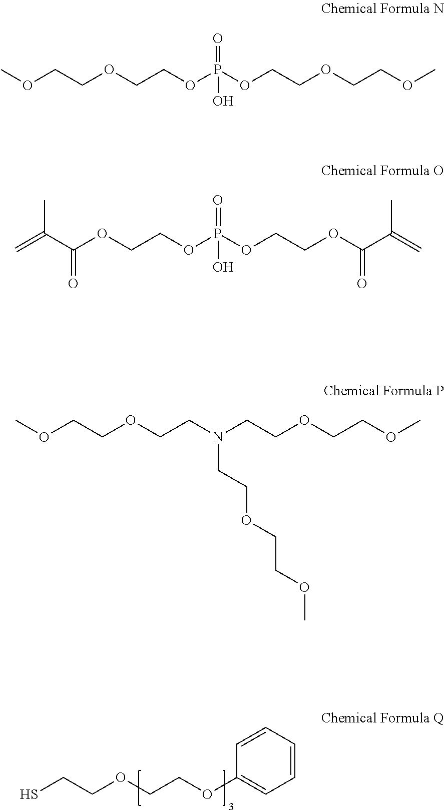

When using any of the aforementioned ligands, the surface modification of the quantum dots is easier, and when the quantum dots surface-modified with the aforementioned ligand are added to the aforementioned polymerizable compound and stirred, a substantially transparent dispersion can be obtained, which may be a measure to confirm that the surface modification of the quantum dots has been successful.

### Light Diffusing Agent

The curable composition according to some example embodiments may further include a light diffusing agent.

For example, the light diffusing agent may include at least one of barium sulfate (BaSO₄), calcium carbonate (CaCO₃), titanium dioxide (TiO₂), zirconia (ZrO₂), or a combination thereof.

The light diffusing agent may reflect unabsorbed light in the aforementioned quantum dots, and allows the quantum dots to absorb the reflected light again. That is, the light diffusing agent may increase an amount of light absorbed by the quantum dots, and increase light conversion efficiency of the curable composition.

The light diffusing agent may have an average particle diameter (D₅₀) in a range of about 150 nm to about 250 nm, and for example about 180 nm to about 230 nm. When the average particle diameter of the light diffusing agent is within any of the above ranges, the light diffusing agent may have a better light diffusing effect, and may increase light conversion efficiency.

The light diffusing agent may be included in an amount in a range of about 1 wt % to about 20 wt %, for example, about 2 wt % to about 15 wt %, for example, about 3 wt % to about 10 wt % based on a total amount of the curable composition. When the light diffusing agent is included in an amount that is less than about 1 wt % based on a total amount of the curable composition, it may be challenging to expect a light conversion efficiency improvement effect due to the use of the light diffusing agent, while when the light diffusing agent is included in an amount greater than about 20 wt %, there is a possibility that the quantum dots may be precipitated.

### Polymerization Initiator

The curable composition according to some example embodiments may further include at least one of a polymerization initiator, for example, a photopolymerization initiator, a thermal polymerization initiator, or a combination thereof.

The photopolymerization initiator is a generally-available initiator for a photosensitive resin composition, for example at least one of an acetophenone-based compound, a benzophenone-based compound, a thioxanthone-based compound, a benzoin-based compound, a triazine-based compound, an oxime-based compound, an aminoketone-based compound, and the like, but is not necessarily limited thereto.

Examples of the acetophenone-based compound may be or include at least one of 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may be or include at least one of benzophenone, benzoyl benzoate, benzoyl methyl benzoate, 4-phenyl benzophenone, hydroxybenzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone-based compound may be or include at least one of thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin-based compound may be or include at least one of benzoin, benzoin methyl ether, benzoin ethyl ether, benzoin isopropyl ether, benzoin isobutyl ether, benzyldimethylketal, and the like.

Examples of the triazine-based compound may be or include at least one of 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime-based compound may be or include at least one of O-acyloxime-based compound, 2-(O-benzoyloxime)-1-[4-(phenylthio)phenyl]-1,2-octandione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Examples of the O-acyloxime-based compound may be or include at least one of 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

Examples of the aminoketone-based compound may be or include at least one of 2-benzyl-2-dimethylamino-1-(4-morpholinophenyl)-butanone-1, and the like.

The photopolymerization initiator may further include at least one of a carbazole-based compound, a diketone-based compound, a sulfonium borate-based compound, a diazo-based compound, an imidazole-based compound, a biimidazole-based compound, and the like, besides the compounds.

The photopolymerization initiator may be used with a photosensitizer capable of causing a chemical reaction by absorbing light and becoming excited, and subsequently transferring the excitation energy.

Examples of the photosensitizer may be or include at least one of tetraethylene glycol bis-3-mercapto propionate, pentaerythritol tetrakis-3-mercapto propionate, dipentaerythritol tetrakis-3-mercapto propionate, and the like.

Examples of the thermal polymerization initiator may be or include at least one of peroxide, for example benzoyl peroxide, dibenzoyl peroxide, lauryl peroxide, dilauryl peroxide, di-tert-butyl peroxide, cyclohexane peroxide, methyl ethyl ketone peroxide, hydroperoxide (e.g., tert-butyl hydroperoxide, cumene hydroperoxide), dicyclohexyl peroxydicarbonate, 2,2-azo-bis(isobutyronitrile), t-butyl perbenzoate, and the like, for example 2,2′-azobis-2-methylpropinonitrile, but are not necessarily limited thereto and any of which is well known in the art may be used.

The polymerization initiator may be included in an amount in a range of about 0.1 wt % to about 5 wt %, for example, about 1 wt % to about 4 wt %, based on a total amount of the curable composition. When the polymerization initiator is included in any of the above ranges, it is possible to obtain desired or improved reliability due to sufficient curing during exposure or thermal curing, and to reduce or prevent deterioration of transmittance due to non-reaction initiators, thereby reducing or preventing deterioration of optical characteristics of the quantum dots.

### Binder Type Resin

The curable composition according to some example embodiments may further include a binder resin.

The binder resin may include at least one of an acrylic resin, a cardo-based resin, an epoxy resin, or a combination thereof.

The acrylic resin may be or include at least one of a copolymer of a first ethylenic unsaturated monomer and a second ethylenic unsaturated monomer that is copolymerizable therewith, and may be resin including at least one acryl-based repeating unit.

Examples of the acrylic resin may be or include at least one of polybenzylmethacrylate, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, but are not limited thereto, and may be included alone or as a mixture of two or more.

A weight average molecular weight of the acrylic resin may be in a range of about 5,000 g/mol to about 15,000 g/mol. When the acrylic resin has a weight average molecular weight within the above range, close contacting properties to a substrate, physical and chemical properties are improved, and the viscosity thereof is appropriate.

An acid value of the acrylic resin may be in a range of about 80 mgKOH/g to about 130 mgKOH/g. When the acrylic resin has an acid value within the above range, desired or improved resolution of a pixel may be obtained.

The cardo-based resin may be used in a conventional curable resin (or photosensitive resin) composition, for example, one suggested in Korean Patent Publication No. 10-2018-0067243 may be used, but is not limited thereto.

The cardo-based resin may be, for example prepared by mixing at least two of a fluorene-containing compound such as 9,9-bis(4-oxiranylmethoxyphenyl) fluorene; an anhydride compound such as at least one of benzenetetracarboxylic acid dianhydride, naphthalenetetracarboxylic acid dianhydride, biphenyltetracarboxylic acid dianhydride, benzophenonetetracarboxylic acid dianhydride, pyromellitic dianhydride, cyclobutanetetracarboxylic acid dianhydride, perylenetetracarboxylic acid dianhydride, tetrahydrofurantetracarboxylic acid dianhydride, and tetrahydrophthalic anhydride; a glycol compound such as at least one of ethylene glycol, propylene glycol, and polyethylene glycol; an alcohol compound such as at least one of methanol, ethanol, propanol, n-butanol, cyclohexanol, and benzylalcohol; a solvent-based compound such as at least one of propylene glycol methylethylacetate, and N-methylpyrrolidone; a phosphorus compound such as at least one of triphenylphosphine; and an amine or ammonium salt compound such as at least one of tetramethylammonium chloride, tetraethylammonium bromide, benzyldiethylamine, triethylamine, tributylamine, or benzyl triethylammonium chloride.

A weight average molecular weight of the cardo-based binder resin may be in a range of about 500 g/mol to about 50,000 g/mol, for example about 1,000 g/mol to about 30,000 g/mol. When the weight average molecular weight of the cardo-based binder resin is within any of the above ranges, a satisfactory pattern may be formed without the formation of a residue during production of a cured layer, and without losing film thickness during development of the curable composition.

When the binder resin is a cardo-based resin, the curable composition including the cardo-based resin, particularly the photosensitive resin composition has desired or improved developability and sensitivity during photo-curing, and thus, desired pattern-forming capability.

The epoxy resin may be or include a thermally polymerizable monomer or oligomer, and may include a compound having a carbon-carbon unsaturated bond and a carbon-carbon cyclic bond.

The epoxy resin may further include at least one of a bisphenol A epoxy resin, a bisphenol F epoxy resin, a phenol novolac epoxy resin, a cyclic aliphatic epoxy resin, and an aliphatic polyglycidyl ether, but is not necessarily limited thereto.

As commercially available products of the compounds, a bisphenyl epoxy resin may be or include at least one of YX4000, YX4000H, YL6121H, YL6640, or YL6677 of Yuka Shell Epoxy Co., Ltd.; a cresol novolac epoxy resin may be or include at least one of EOCN-102, EOCN-103S, EOCN-104S, EOCN-1020, EOCN-1025, and EOCN-1027 of Nippon Kayaku Co., Ltd. and EPIKOTE 180S75, and the like of Yuka Shell Epoxy Co., Ltd.; a bisphenol A epoxy resin may be or include at least one of EPIKOTE 1001, 1002, 1003, 1004, 1007, 1009, 1010, and 828 of Yuka Shell Epoxy Co., Ltd.; a bisphenol F epoxy resin may be or include at least one of EPIKOTE 807 and 834 of Yuka Shell Epoxy Co., Ltd.; a phenol novolac epoxy resin may be or include at least one of EPIKOTE 152, 154, or 157H65 of Yuka Shell Epoxy Co. and EPPN 201, 202 of Nippon Kayaku Co., Ltd. and EPPN 201, 202 of Nippon Kayaku Co., Ltd.; a cyclic aliphatic epoxy resin may be or include at least one of CY175, CY177, and CY179 of CIBA-GEIGY A.G Corp., ERL-4234, ERL-4299, ERL-4221 and ERL-4206 of U.C.C., Showdyne 509 of Showa Denko K.K., Araldite CY-182, CY-192 and CY-184 of CIBA-GEIGY A.G Corp., EPICLON 200 and 400 of Dainippon Ink & Chemicals Inc., EPIKOTE 871 and 872, and EP1032H60 of Yuka Shell Epoxy Co., Ltd., ED-5661 and ED-5662 of Celanese Coating Corporation; an aliphatic polyglycidylether may be or include at least one of EPIKOTE 190P and 191P of Yuka Shell Epoxy Co., Ltd., EPOLITE 100MF of Kyoeisha Yushi Kagaku Kogyo Co., Ltd., EPIOL TMP of Nihon Yushi K. K., and the like.

For example, when the curable composition according to some example embodiments is a solvent-free curable composition, the binder resin may be included in an amount in a range of about 0.5 wt % to about 10 wt %, for example, about 1 wt % to about 5 wt %, based on a total amount of the curable composition. In this case, the heat resistance and the chemical resistance of the solvent-free curable composition may be improved, as well as the storage stability of the composition.

For example, when the curable composition according to some example embodiments is a curable composition including a solvent, the binder resin may be included in an amount in a range of about 1 wt % to about 30 wt %, for example, about 3 wt % to about 20 wt %, based on a total amount of the curable composition. In this case, the curable composition may improve pattern characteristics, heat resistance, and chemical resistance.

### Other Additive

For stability and dispersion improvement of the quantum dot, the curable composition according to some example embodiments may further include a polymerization inhibitor.

The polymerization inhibitor may include at least one of a hydroquinone-based compound, a catechol-based compound, or a combination thereof, but is not necessarily limited thereto. When the curable composition according to some example embodiments further includes the at least one of the hydroquinone-based compound, the catechol-based compound, or the combination thereof, room temperature cross-linking during exposure after coating the curable composition may be reduced or prevented.

For example, the hydroquinone-based compound, the catechol-based compound, or the combination thereof may be or include at least one of hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum, or a combination thereof, but are not necessarily limited thereto.

The hydroquinone-based compound, the catechol-based compound, or the combination thereof may be included in a form of dispersion. The polymerization inhibitor in a form of dispersion may be included in an amount in a range of about 0.001 wt % to about 3 wt %, for example about 0.01 wt % to about 2 wt % based on a total amount of the curable composition. When the polymerization inhibitor is included in any of the above ranges, passage of time at room temperature may be solved, and simultaneously or contemporaneously, sensitivity deterioration and surface delamination phenomenon may be reduced or prevented.

In addition, the curable composition according to some example embodiments may further include at least one of malonic acid; 3-amino-1,2-propanediol; a silane-based coupling agent; a leveling agent; a fluorine-based surfactant; or a combination thereof in order to improve heat resistance and reliability.

For example, the curable composition according to example embodiment may further include at least one of a silane-based coupling agent having a reactive substituent such as a vinyl group, a carboxyl group, a methacryloxy group, an isocyanate group, an epoxy group, and the like in order to improve close contacting properties with a substrate.

Examples of the silane-based coupling agent may be or include at least one of trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-epoxycyclohexylethyltrimethoxysilane, and the like, and these may be included alone or in a mixture of two or more.

The silane-based coupling agent may be included in an amount in a range of about 0.01 parts by weight to about 10 parts by weight based on 100 parts by weight of the curable composition. When the silane-based coupling agent is included within the above range, close contacting properties, storage capability, and the like are improved.

In addition, the curable composition may further include a surfactant, for example a fluorine-based surfactant as needed in order to improve coating properties and inhibit generation of spots, that is, improve leveling performance.

The fluorine-based surfactant may have a low weight average molecular weight in a range of about 4,000 g/mol to about 10,000 g/mol, and for example about 6,000 g/mol to about 10,000 g/mol. In addition, the fluorine-based surfactant may have a surface tension in a range of about 18 mN/m to about 23 mN/m (measured in a 0.1% polyethylene glycol monomethylether acetate (PGMEA) solution). When the fluorine-based surfactant has a weight average molecular weight and a surface tension within the above ranges, leveling performance may be further improved, and desired or improved characteristics may be provided when slit coating as high-speed coating is applied because film defects may be less likely to be generated by reducing or preventing a spot generation during the high-speed coating and reducing or suppressing a vapor generation.

Examples of the fluorine-based surfactant may be or include at least one of, BM-1000® and BM-1100® (BM Chemie Inc.); MEGAFACE F 142D®, F 172®, F 173®, and F 183® Dainippon Ink Kagaku Kogyo Co., Ltd.); FULORAD FC-135®, FULORAD FC-170C® FULORAD FC-430®, and FULORAD FC-431® (Sumitomo 3M Co., Ltd.); SURFLON S-112®, SURFLON S-113®, SURFLON S-131®, SURFLON S-141®, and SURFLON S-145® (ASAHI Glass Co., Ltd.); and SH-28PAR, SH-190®, SH-193®, SZ-6032®, and SF-8428®, and the like (Toray Silicone Co., Ltd.); F-482, F-484, F-478, F-554 and the like of DIC Co., Ltd.

In addition, the curable composition according to some example embodiments may include a silicone-based surfactant in addition to the fluorine-based surfactant. Examples of the silicone-based surfactant may be or include at least one of TSF400, TSF401, TSF410, TSF4440, and the like of Toshiba silicone Co., Ltd., but are not limited thereto.

The surfactant may be included in an amount in a range of about 0.01 parts by weight to about 5 parts by weight, for example about 0.1 parts by weight to about 2 parts by weight based on 100 parts by weight of the curable composition. When the surfactant is included within any of the above ranges, foreign materials are less likely to be produced in a sprayed composition.

In addition, the curable composition according to some example embodiments may further include other additives such as, e.g., an antioxidant, a stabilizer, and the like in a predetermined or desired amount, unless properties of the curable composition are deteriorated as a result of the addition.

### Solvent

The curable composition according to some example embodiments may further include a solvent.

The solvent may for example may include at least one of alcohols such as methanol, ethanol, and the like; glycol ethers such as ethylene glycol methylether, ethylene glycol ethylether, propylene glycol methylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol monomethylether acetate, propylene glycol propylether acetate, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; hydroxy acetic acid alkyl esters such as methyl hydroxyacetate, ethyl hydroxyacetate, butyl hydroxyacetate, and the like; acetic acid alkoxyalkyl esters such as methoxymethyl acetate, methoxyethyl acetate, methoxybutyl acetate, ethoxymethyl acetate, ethoxyethyl acetate, and the like; 3-hydroxypropionic acid alkyl esters such as methyl 3-hydroxypropionate, ethyl 3-hydroxypropionate, and the like; 3-alkoxypropionic acid alkyl esters such as methyl 3-methoxypropionate, ethyl 3-methoxypropionate, ethyl 3-ethoxypropionate, methyl 3-ethoxypropionate, and the like; 2-hydroxypropionic acid alkyl ester such as methyl 2-hydroxypropionate, ethyl 2-hydroxypropionate, propyl 2-hydroxypropionate, and the like; 2-alkoxypropionic acid alkyl esters such as methyl 2-methoxypropionate, ethyl 2-methoxypropionate, ethyl 2-ethoxypropionate, methyl 2-ethoxypropionate, and the like; 2-hydroxy-2-methylpropionic acid alkyl esters such as methyl 2-hydroxy-2-methylpropionate, ethyl 2-hydroxy-2-methylpropionate, and the like; 2-alkoxy-2-methylpropionic acid alkyl esters such as methyl 2-methoxy-2-methylpropionate, ethyl 2-ethoxy-2-methylpropionate, and the like; esters such as 2-hydroxyethyl propionate, 2-hydroxy-2-methylethyl propionate, hydroxyethyl acetate, methyl 2-hydroxy-3-methylbutanoate, and the like; or ketonate esters such as ethyl pyruvate, and the like, and in addition, may be N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and the like, but is not limited thereto.

For example, the solvent may be or include at least one of glycol ethers such as ethylene glycol monoethylether, ethylene diglycolmethylethylether, and the like; ethylene glycol alkylether acetates such as ethyl cellosolve acetate, and the like; esters such as 2-hydroxy ethyl propionate, and the like; carbitols such as diethylene glycol monomethylether, and the like; propylene glycol alkylether acetates such as propylene glycol monomethylether acetate, propylene glycol propylether acetate, and the like; alcohols such as ethanol, and the like, or a combination thereof.

For example, the solvent may be or include a polar solvent including at least one of propylene glycol monomethylether acetate, dipropylene glycol methylether acetate, ethanol, ethylene glycoldimethylether, ethylenediglycolmethylethylether, diethylene glycoldimethylether, 2-butoxyethanol, N-methylpyrrolidine, N-ethylpyrrolidine, propylene carbonate, γ-butyrolactone, or a combination thereof.

The solvent may be included in an amount in a range of about 40 wt % to about 80 wt %, for example, about 45 wt % to about 80 wt %, based on a total amount of the curable composition. When the solvent is within any of the above ranges, the solvent type curable composition has a desired viscosity, and thus may have desired or improved coating property when coated in a large area through, e.g., spin-coating and slit-coating.

Some example embodiments include a cured layer manufactured using the aforementioned curable composition, a color filter including the cured layer, and a display device including the color filter.

One of a number of methods of producing the cured layer may include coating the curable composition and solvent type curable composition on a substrate using an ink-jet spraying method to form a pattern (S1); and curing the pattern (S2).

### (S1) Formation of Pattern

The curable composition may desirably be coated to be about 0.5 μm to about 20 μm on a substrate in an ink-jet spraying method. The ink-jet spraying method may form a pattern by spraying a single color per each nozzle, and thus repeating the spraying as many times as the needed number of colors, but the pattern may be formed by simultaneously or contemporaneously spraying the needed number of colors through each ink-jet nozzle in order to reduce processes.

### (S2) Curing

The obtained pattern is cured to obtain a pixel. Herein, the curing method may be thermal curing or photocuring process. The thermal curing process may be performed at a temperature that is greater than or equal to about 100° C., such as, e.g., in a range of about 100° C. to about 300° C., or in a range of about 160° C. to about 250° C. The photocuring process may include irradiating an actinic ray such as a UV ray in a range of about 190 nm to about 450 nm, for example about 200 nm to about 500 nm. Light sources used for irradiation include low-pressure mercury lamps, high-pressure mercury lamps, ultra-high pressure mercury lamps, metal halide lamps, argon gas lasers, and in some cases, X-rays and electron beams.

Another method of producing the cured layer may include producing a cured layer using the aforementioned curable composition or solvent type curable composition by a lithographic method as follows.

### (1) Coating and Film Formation

The curable composition is coated to have a desired thickness, for example, a thickness ranging from about 2 μm to about 10 μm, on a substrate which undergoes a predetermined pretreatment, using a spin or slit coating method, a roll coating method, a screen-printing method, an applicator method, and the like. Then, the coated substrate is heated at a temperature in a range of about 70° C. to about 90° C. for a period of time in a range of about 1 minute to about 10 minutes to remove a solvent and to form a film.

### (2) Exposure

The resultant film is irradiated by an actinic ray such as a UV ray in a range of about 190 nm to about 450 nm, for example about 200 nm to about 500 nm after putting a mask with a predetermined shape to form a desired pattern. A light source used for irradiation include low-pressure mercury lamps, high-pressure mercury lamps, ultra-high pressure mercury lamps, metal halide lamps, argon gas lasers, and in some cases, X-rays and electron beams.

Exposure process uses, for example, a light dose of 500 mJ/cm² or less (with a 365 nm sensor) when a high-pressure mercury lamp is used. The light dose may vary depending on types of each component of the curable composition, a combination ratio of each component, and a dry film thickness.

### (3) Development

After the exposure process, an alkali aqueous solution is used to develop the exposed film by dissolving and removing unnecessary potions other than the exposed portion, forming an image pattern. In other words, when the alkali developing solution is used for the development, an unexposed region is dissolved, and an image color filter pattern is formed.

### (4) Post-Treatment

The developed image pattern may be heated again or irradiated by an actinic ray and the like for curing, in order to accomplish desired or improved quality in terms of heat resistance, light resistance, close contacting properties, crack-resistance, chemical resistance, high strength, storage stability, and the like.

Hereinafter, the present disclosure is illustrated in more detail with reference to examples. These examples, however, are not in any sense to be interpreted as limiting the scope of the disclosure.

### Preparation of Polymerizable Compounds

### Preparation Example 1

16.3 g of 1,4-butanedithiol was sufficiently dissolved in 100 mL of toluene. 47.34 g of 3-chloropropionyl chloride was added thereto, and the reaction was terminated after stirring at 50° C. for 12 hours. The reaction solution was extracted using 100 ml of water and 150 mL of DCM. MgSO₄ was added to the separated organic layer, stirred for 5 minutes, and filtered, and the filtrate was concentrated. After column purification, the filtrate was concentrated and vacuum dried.

33 g of the dried intermediate was sufficiently dissolved in 150 mL of acetone and stirred at 0° C. for 10 minutes. 45.5 g of triethylamine was added, stirred for an additional 10 minutes, and the reaction was terminated after stirring at 50° C. for 12 hours. The reaction solution was extracted using 100 mL of 1N HCl aqueous solution and 150 mL of DCM. MgSO₄ was added to the separated organic layer, stirred for 5 minutes, and filtered, and the filtrate was concentrated. After column purification, concentration and vacuum drying were performed to prepare a compound represented by Chemical Formula 1-1 (refractive index: 1.5508, viscosity: 7.3).

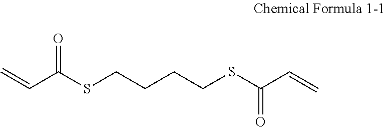

### Preparation Example 2

18.6 g of bis(2-mercaptoethyl) ether was sufficiently dissolved in 100 mL of toluene. 51.3 g of 3-chloropropionyl chloride was added here, and the reaction was terminated after stirring at 50° C. for 12 hours. The reaction solution was extracted using 100 ml of water and 150 mL of DCM. MgSO₄ was added to the separated organic layer, stirred for 5 minutes, and filtered, and the filtrate was concentrated. After column purification, the filtrate was concentrated and vacuum dried.

34 g of the dried intermediate was sufficiently dissolved in 150 mL of acetone and stirred at 0° C. for 10 minutes. 44.5 g of triethylamine was added, stirred for an additional 10 minutes, and the reaction was terminated after stirring at 50° C. for 12 hours. The reaction solution was extracted using 100 mL of 1N HCl aqueous solution and 150 mL of DCM. MgSO₄ was added to the separated organic layer, stirred for 5 minutes, and filtered, and the filtrate was concentrated. After column purification, concentration and vacuum drying were performed to prepare a compound represented by Chemical Formula 1-2 compound (refractive index: 1.5455, viscosity: 10.1).

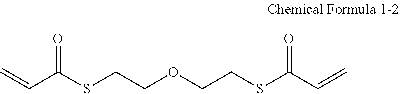

### Preparation Example 3

24 g of 6-mercapto-1-hexanol was sufficiently dissolved in 100 mL of toluene. 62.41 g of 3-chloropropionyl chloride was added thereto, and the reaction was terminated after stirring at 50° C. for 12 hours. The reaction solution was extracted using 100 mL of water and 150 mL of DCM. MgSO₄ was added to the separated organic layer, stirred for 5 minutes, and filtered, and the filtrate was concentrated. After column purification, the filtrate was concentrated and vacuum dried.

50 g of the dried intermediate was sufficiently dissolved in 150 mL of acetone and stirred at 0° C. for 10 minutes. 44.5 g of triethylamine was added, stirred for an additional 10 minutes, and the reaction was terminated after stirring at 50° C. for 12 hours. The reaction solution was extracted using 100 mL of 1N HCl aqueous solution and 150 mL of DCM. MgSO₄ was added to the separated organic layer, stirred for 5 minutes, and filtered, and the filtrate was concentrated. After column purification, concentration and vacuum drying were performed to prepare a compound represented by Chemical Formula 1-3 (refractive index: 1.4987, viscosity: 7.1).

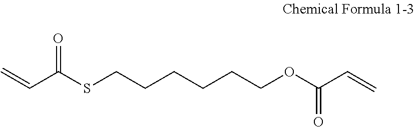 [SMILES: C=CC(=O)OCCCCCCSC(=O)C=C]

### Preparation of Surface-Modified Quantum Dot Dispersion

### Preparation Example 4

After placing a magnetic bar in a 3-necked round bottom flask, a green quantum dot dispersion solution (InP/ZnSe/ZnS, Hansol Chemical, a quantum dot solid content: 23 wt %) was added therein. Subsequently, a compound (ligand) represented by Chemical Formula Q was added thereto and then, stirred at 80° C. under a nitrogen atmosphere. When a reaction was completed, after cooling to room temperature (23° C.), a quantum dot reaction solution was added to cyclohexane to catch precipitates. The precipitates were separated from the cyclohexane through centrifugation and then, sufficiently dried in a vacuum oven for 24 hours to obtain surface-modified quantum dots.

The surface-modified green quantum dots were stirred with a polymerizable compound for 12 hours to obtain surface-modified quantum dot dispersion (QD solid content: 23 wt %).
(*Synthesis of the compound represented by Chemical Formula Q: 100 g of PH-4 (Hannong Chemicals Inc.) was placed in a 2-necked round bottom flask and then, sufficiently dissolved in 300 mL of THF. Then, 15.4 g of NaOH and 100 mL of water were added thereto at 0° C. and then, sufficiently dissolved until a clear solution was obtained. A solution prepared by dissolving 73 g of para-toluene sulfonic chloride in 100 mL of THF was slowly injected thereinto at 0° C. The injection was performed for 1 hour, and then, the obtained mixture was stirred at room temperature for 12 hours. When a reaction was completed, an excessive amount of methylene chloride was added thereto and then, stirred, and a NaHCO₃ saturated solution was added thereto to proceed with extraction, titration, and moisture removal. After removing the solvent, the residue was dried in a dry oven for 24 hours. 50 g of the dried product was added in a 2-necked round bottom flask and sufficiently stirred with 300 mL of ethanol. Subsequently, 27 g of thiourea was added thereto and dispersed therein and then, refluxed at 80° C. for 12 hours. Subsequently, an aqueous solution, in which 4.4 g of NaOH was dissolved in 20 mL of water, was injected thereinto, while further stirred for 5 hours, an excessive amount of methylene chloride was added thereto and then, stirred, and a hydrochloric acid aqueous solution was added thereto and then, proceeded sequentially with extraction, titration, moisture removal, and solvent removal. Then, drying in a vacuum oven for 24 hours was performed to obtain a compound represented by Chemical Formula Q.)

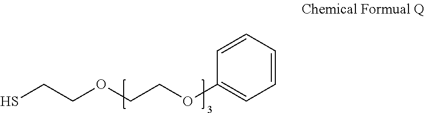

### Preparation of Curable Compositions

### Examples 1 to 5 and Comparative Examples 1 and 2

Each curable composition Examples 1 to 5 and Comparative Examples 1 and 2 was prepared by using the following components to have each composition shown in Tables 1 and 2.

The quantum dot dispersion was weighed and diluted by mixing with a polymerizable compound, and the polymerization inhibitor was added thereto and stirred for 5 minutes. Subsequently, a photoinitiator was added thereto, and a light diffusing agent was added thereto. Then, a corresponding composition was stirred for 1 hour to prepare a curable composition.

### (A) Quantum Dots

Surface-modified green quantum dot dispersion prepared from Preparation Example 4

### (B) Polymerizable Compound

(B-1) Compound of Preparation Example 1 (first polymerizable compound)
(B-2) Compound of Preparation Example 2 (first polymerizable compound)
(B-3) Compound of Preparation Example 3 (first polymerizable compound)
(B-4) Compound represented by Chemical Formula 2-2 (M200, Miwon Chemical Co., Ltd.) (refractive index: 1.455, viscosity: 6.1 centipoise (cps)) (second polymerizable compound)

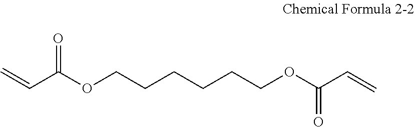 [SMILES: C=CC(=O)OCCCCCCOC(=O)C=C]

### (C) Photopolymerization Initiator

TPO-L (Polynetron Co., Ltd.)

### (D) Light Diffusing Agent

Titanium dioxide dispersion (TiO₂ solid content: 20 wt %, average particle diameter: 200 nm, Dito Technology Co., Ltd.)

### (E) Polymerization Inhibitor

Methylhydroquinone (TOKYO CHEMICAL Co., Ltd.)

TABLE 1
(unit: wt %)

| | | Example | Example | Example | Example | Example | Comparative | Comparative |
|---|---|---|---|---|---|---|---|---|
| | | 1 | 2 | 3 | 4 | 5 | Example 1 | Example 2 |
| (A) quantum dot | | 38 | 38 | 38 | 38 | 38 | 41 | 38 |
| dispersion | | | | | | | | |
| (B) | B-1 | 8.24 | 16.49 | 24.73 | — | — | — | — |
| polymerizable | B-2 | — | | — | 8.24 | — | — | — |
| compound | B-3 | — | — | — | — | 8.24 | — | — |
| | B-4 | 46.71 | 38.46 | 30.22 | 46.71 | 46.71 | 51.95 | 54.95 |

| | | | | | | | |
|---|---|---|---|---|---|---|---|
| (C) | 3 | 3 | 3 | 3 | 3 | 3 | 3 |
| photopolymerization | | | | | | | |
| initiator | | | | | | | |
| (D) light diffusing | 4 | 4 | 4 | 4 | 4 | 4 | 4 |
| agent | | | | | | | |
| (E) polymerization | 0.05 | 0.05 | 0.05 | 0.05 | 0.05 | 0.05 | 0.05 |
| inhibitor | | | | | | | |
| total | 100 | 100 | 100 | 100 | 100 | 100 | 100 |

### Evaluation of Optical Characteristics and Diffuse Reflectance of Curable Composition

Each of the curable compositions Examples 1 to 5 and Comparative Examples 1 and 2 was measured with respect to quantum efficiency (EQE) after the exposure and diffuse reflectance (SCE) after the curing by using a spectrophotometer (CM-3600A, Konica Minolta, Inc.), and the results are shown in Table 2.

TABLE 2

| | Quantum efficiency | Diffuse reflectance |
|---|---|---|
| | after exposure (%) | after curing (%) |
| Example 1 | 30.7 | 53.4 |
| Example 2 | 31.0 | 52.5 |
| Example 3 | 31.4 | 51.3 |
| Example 4 | 30.5 | 53.8 |
| Example 5 | 30.1 | 54.5 |
| Comparative Example 1 | 29.7 | 57.8 |
| Comparative Example 2 | 29.5 | 56.0 |

Referring to Table 2, the curable compositions of Examples 1 to 5, compared with the curable compositions of Comparative Examples 1 and 2, exhibited improved optical characteristics due to high quantum efficiency after the exposure, and contemporaneously reduced reflectance effects due to low diffuse reflectance after the curing.

While this disclosure has been described in connection with what is presently considered to be practical example embodiments, it is to be understood that the disclosure is not limited to the disclosed example embodiments, but, on the contrary, is intended to cover various modifications and equivalent arrangements included within the spirit and scope of the appended claims. Therefore, the aforementioned embodiments should be understood to be examples but do not limit the present disclosure in any way.

What is claimed is:

1. A curable composition, comprising
quantum dots; and
a polymerizable compound including a first polymerizable compound represented by Chemical Formula 1: 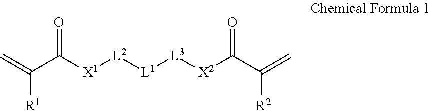
wherein, in Chemical Formula 1,
R¹ and R² each independently comprise a hydrogen atom or a substituted or unsubstituted C1 to C20 alkyl group,
L¹ to L³ each independently comprise at least one of a single bond, an ether group (*—O—*), and a substituted or unsubstituted C1 to C20 alkylene group, and
X¹ and X² each independently comprise at least one of an ether group (*—O—*) and a sulfide group (*—S—*), wherein at least one of X¹ and X² comprises a sulfide group (*—S—*).

2. The curable composition as claimed in claim 1, wherein L¹ comprises at least one of a single bond, an ether group (*—O—*), and a substituted or unsubstituted C1 to C20 alkylene group.

3. The curable composition as claimed in claim 1, wherein L² and L³ each independently comprise a substituted or unsubstituted C1 to C20 alkylene group.

4. The curable composition as claimed in claim 1, wherein the first polymerizable compound has a refractive index that is equal to or greater than about 1.49, and a viscosity that is equal to or greater than about 7.0.

5. The curable composition as claimed in claim 1, wherein the first polymerizable compound is represented by any one of Chemical Formula 1-1 to Chemical Formula 1-3:

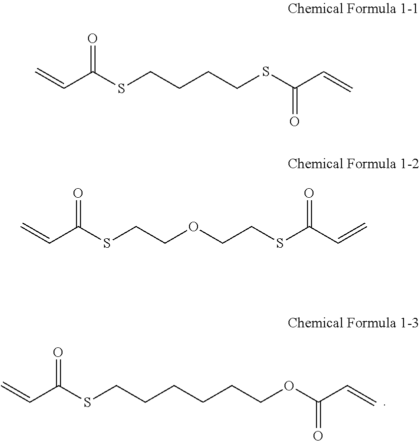

6. The curable composition as claimed in claim 1, wherein the polymerizable compound further comprises a second polymerizable compound having a different structure from the first polymerizable compound.

7. The curable composition as claimed in claim 6, wherein the second polymerizable compound comprises a compound represented by Chemical Formula 2: 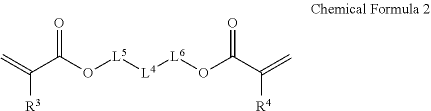
wherein, in Chemical Formula 2,
L⁴ comprises at least one of a substituted or unsubstituted C1 to C10 alkylene group, a substituted or unsubstituted C3 to C20 cycloalkylene group, or an ether group (*—O—*),
L⁵ and L⁶ each independently comprise a single bond or a substituted or unsubstituted C1 to C10 alkylene group, and
R³ and R⁴ each independently comprise a hydrogen atom or a substituted or unsubstituted C1 to C20 alkyl group.

8. The curable composition as claimed in claim 7, wherein the first polymerizable compound and the second polymerizable compound are included in a weight ratio in a range of about 1:9 to about 9:1.

9. The curable composition as claimed in claim 8, wherein the first polymerizable compound and the second polymerizable compound are included in a weight ratio in a range of about 1:9 to about 5:5.

10. The curable composition as claimed in claim 1, wherein the curable composition is a solvent-free curable composition.

11. The solvent-free curable composition as claimed in claim 10, wherein based on a total amount of the solvent-free curable composition,
the solvent-free curable composition comprises about 5 wt % to about 60 wt % of the quantum dots and about 40 wt % to about 95 wt % of the polymerizable compound.

12. The curable composition as claimed in claim 1, wherein the curable composition further comprises at least one of a polymerization initiator, a light diffusing agent, and a polymerization inhibitor.

13. The curable composition as claimed in claim 12, wherein the light diffusing agent comprises at least one of barium sulfate, calcium carbonate, titanium dioxide, and zirconia.

14. The curable composition as claimed in claim 1, wherein the curable composition further comprises a solvent.

15. The curable composition as claimed in claim 14, wherein the curable composition comprises about 1 wt % to about 40 wt % of the quantum dots, about 1 wt % to about 20 wt % of the polymerizable compound, and about 40 wt % to about 80 wt % of the solvent based on a total weight of the curable composition.

16. The curable composition as claimed in claim 1, wherein the curable composition further comprises at least one of malonic acid; 3-amino-1,2-propanediol; a silane-based coupling agent; a leveling agent; and a fluorine-based surfactant.

17. A cured layer manufactured comprising the curable composition as claimed in claim 1.

18. A color filter comprising the cured layer as claimed in claim 17.

19. A display device comprising the cured layer as claimed in claim 17.
